(19) United States
(12) Patent Application Publication
(10) Pub. No.: US 2012/0325536 A1
(43) Pub. Date: Dec. 27, 2012

(54) DISPLAY DEVICE AND METHOD FOR FABRICATING SAME

(75) Inventor: Misuzu Negoro, Osaka-shi (JP)

(73) Assignee: SHARP KABUSHIKI KAISHA, Osaka-shi, Osaka (JP)

(21) Appl. No.: 13/581,964

(22) PCT Filed: Nov. 9, 2010
(86) PCT No.: PCT/JP2010/006562

§ 371 Date: Aug. 30, 2012

(30) Foreign Application Priority Data
Mar. 2, 2010 (JP) 2010-045637

(51) Int. Cl. H05K 1/16; B32B 37/12

(52) U.S. Cl. 174/260; 156/295

(57) ABSTRACT

A display device includes a display panel having a first substrate a second substrate facing the first substrate, and a translucent panel attached, via an adhesive layer, to a surface of the second substrate opposite a surface facing the first substrate. The first substrate includes a terminal region which does not face the second substrate and in which a plurality of terminals are provided. A circuit component is mounted on the terminals in the terminal region. At least part of the circuit component is covered by the adhesive layer extending from between the second substrate and the translucent panel to the terminal region.

### TECHNICAL FIELD

The present invention relates to display devices, such as liquid crystal display devices, and methods for fabricating the display devices.

### BACKGROUND ART

Thin display devices, such as liquid crystal display devices, include a display panel and a circuit component, such as a circuit chip and a flexible printed circuit (FPC) provided on the display panel (see, e.g., Patent Document 1), and the display devices are widely used as display devices of mobile phones, televisions, etc.

Further, in recent years, display devices which display three dimensional images, and so-called dual view display devices which display two different types of images at the same time are being developed. These display devices include a parallax barrier panel attached to a surface of the display panel with an adhesive layer interposed therebetween (see, e.g., Patent Document 2).

Steps for fabricating a liquid crystal display device having a parallax barrier panel will be described below with reference to FIG. 9 to FIG. 12. FIG. 9 to FIG. 12 are plan views for describing steps of fabricating a conventional liquid crystal display device.

First, to fabricate a liquid crystal display device, a liquid crystal display panel 101 is formed by attaching a first substrate 102 and a second substrate 103 to each other with a liquid crystal material interposed therebetween, as shown in FIG. 9. The first substrate 102 is larger than the second substrate 103. A terminal region 104 is formed in an area where the first substrate 102 extends off the second substrate 103. A plurality of terminals (not shown) are provided in the terminal region 104.

Next, as shown in FIG. 10, an adhesive 105, such as resin, is applied to a surface of the second substrate 103, and then, a parallax barrier panel 106 is attached to the second substrate 103 with the adhesive 105 interposed therebetween. To attach the parallax barrier panel 106 to the second substrate 103 without unevenness, the adhesive 105 needs to be applied rather thickly to the entire surface of the second substrate 103. Thus, as shown in FIG. 11, the adhesive 105 may be squeezed out from between the parallax barrier panel 106 and the second substrate 103 to the terminal region 104.

Accordingly, in the next step, the adhesive 105 squeezed out is removed from the terminal region 104 and is cleaned. After exposing the terminals in the terminal region 104 by removing the adhesive 105, circuit chips 108 and an FPC 109 are mounted on the terminals. A liquid crystal display device 100 is fabricated in this manner.

### CITATION LIST

### Patent Document

Patent Document 1: Japanese Utility Model Publication No. 5-020034
Patent Document 2: Japanese Patent Publication No. 2009-192660

### SUMMARY OF THE INVENTION

### Technical Problem

In the above conventional display device, it is difficult to reduce the number of fabrication steps because the adhesive needs to be removed from the terminal region and cleaned. Further, the terminals may be separated from the first substrate when the adhesive is removed from the terminal region.

The present invention was made in view of the above problems, and a main objective of the invention is to increase fabrication yield of display devices while reducing the number of steps of fabricating the display devices.

### Solution to the Problem

To achieve the above objective, in the present invention, at least part of a circuit component mounted on a terminal in a terminal region of the first substrate is covered by an adhesive layer extending from between a second substrate and a translucent panel.

Specifically, the present invention is directed to a display device including a display panel including a first substrate and a second substrate facing the first substrate, and a translucent panel attached, via an adhesive layer, to a surface of the second substrate opposite a surface facing the first substrate.

The first substrate includes a terminal region which does not face the second substrate and in which a plurality of terminals are provided; a circuit component is mounted on the terminals in the terminal region; and at least part of the circuit component is covered by the adhesive layer extending from between the second substrate and the translucent panel to the terminal region.

### Effects

Effects of the present invention will be described below.

In the present invention, at least part of the circuit component mounted on the terminals in the terminal region can be covered by the adhesive layer extending from between the second substrate and the translucent panel. Thus, unlike the conventional cases, the adhesive layer does not need to be removed from the terminal region and cleaned. This eliminates the need to perform a step of cleaning the adhesive layer. Accordingly, the number of steps necessary for fabricating the display device can be reduced. Further, since the adhesive layer is not removed from the terminal region, it is possible to prevent separation of the terminals associated with the removal step. As a result, it is possible to significantly increase the yield, while reducing the time necessary for the fabrication.

Moreover, the circuit component can be protected by the adhesive layer which is for attaching the translucent panel to the second substrate. Thus, the circuit component can be more firmly mounted on the terminal in the terminal region without an increase in the number of steps.

### Advantages of the Invention

According to the present invention, at least part of the circuit component mounted on the terminal in the terminal region of the first substrate is covered by the adhesive layer extending from between the second substrate and the translucent panel. Thus, it is possible to increase the yield, while reducing the number of steps necessary for the fabrication of the display device.

### BRIEF DESCRIPTION OF THE DRAWINGS

FIG. 1 is a plan view which illustrates an external view of a main part of a liquid crystal display device according to the present first embodiment.

FIG. 2 is a cross section taken along the line II-II of FIG. 1.

FIG. 3 is a plan view which illustrates a liquid crystal display panel before attachment of a parallax barrier panel.

FIG. 4 is a plan view which illustrates a liquid crystal display panel to which an adhesive is applied, and a parallax barrier panel to be attached to the liquid crystal display panel.

FIG. 5 is a plan view which illustrates an external view of a main part of a liquid crystal display device according to the present second embodiment.

FIG. 6 is a cross section taken along the line VI-VI of FIG. 5.

FIG. 7 is a plan view which illustrates an external view of a main part of a liquid crystal display device according to the present third embodiment.

FIG. 8 is a cross section taken along the line VIII-VIII of FIG. 7.

FIG. 9 is a plan view for explaining a step of fabricating a conventional liquid crystal display device.

FIG. 10 is a plan view for explaining a step of fabricating a conventional liquid crystal display device.

FIG. 11 is a plan view for explaining a step of fabricating a conventional liquid crystal display device.

FIG. 12 is a plan view for explaining a step of fabricating a conventional liquid crystal display device.

### DESCRIPTION OF EMBODIMENTS

Embodiments of the present invention will be described in detail below based on the drawings. The present invention is not limited to the following embodiments.

### First Embodiment of Invention

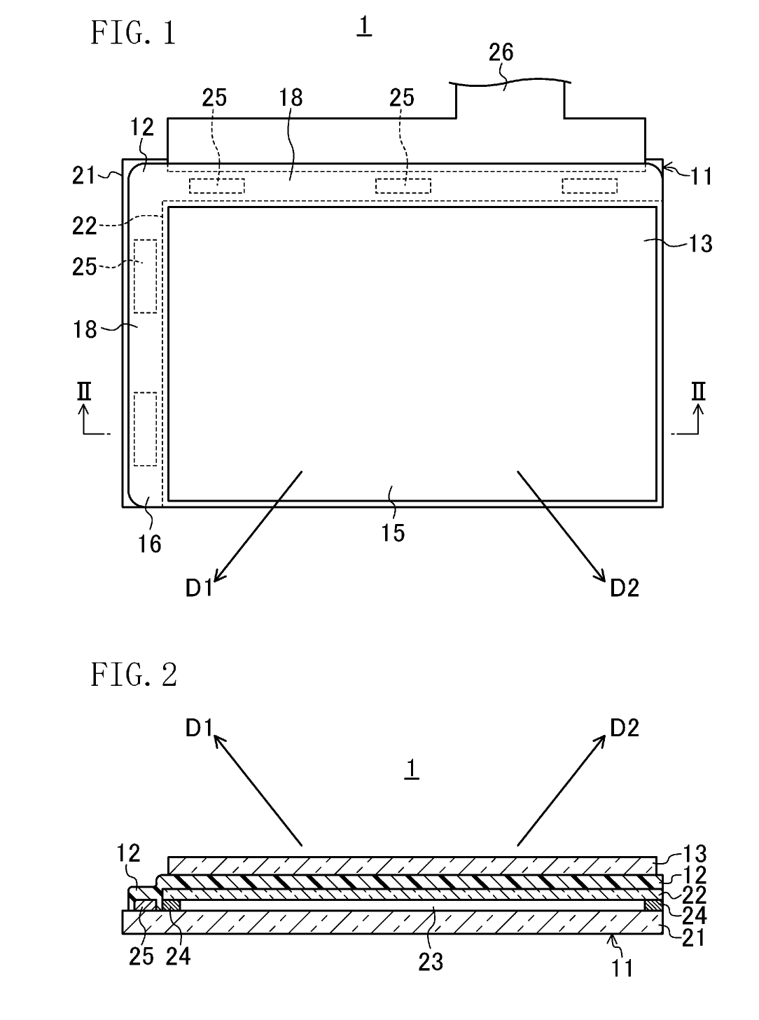

FIG. 1 to FIG. 4 show the first embodiment of the present invention.

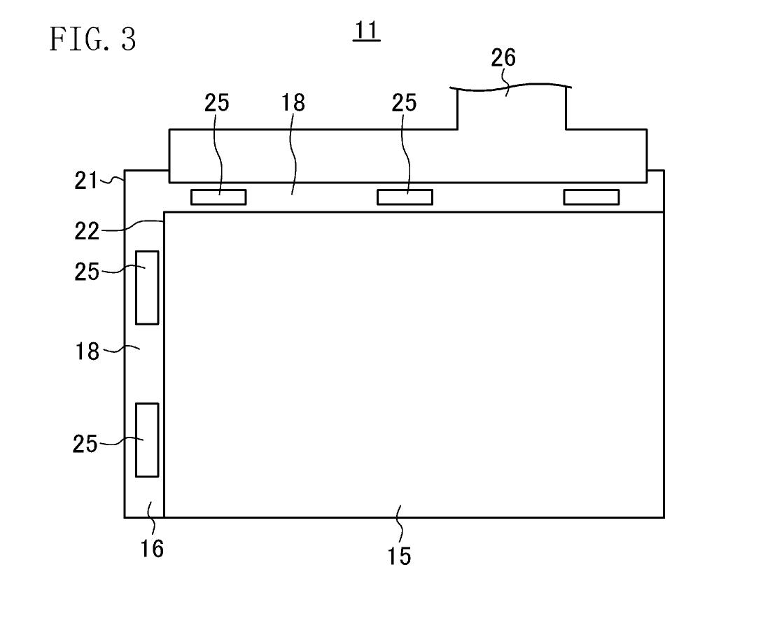

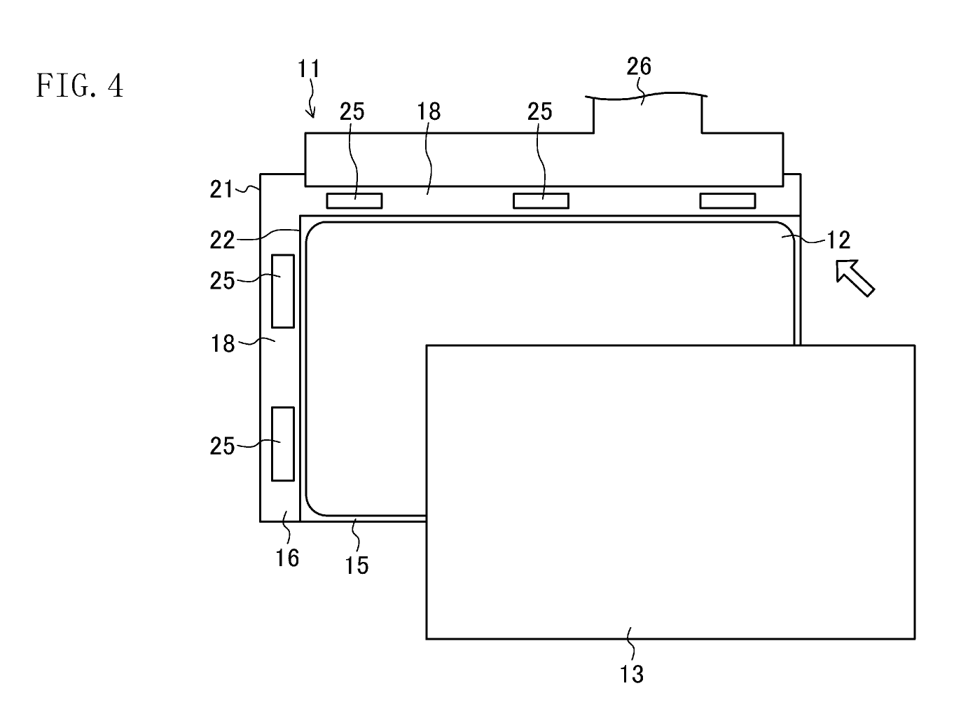

FIG. 1 is a plan view which illustrates an external view of a main part of a liquid crystal display device 1 according to the present first embodiment. FIG. 2 is a cross section taken along the line II-II of FIG. 1. FIG. 3 is a plan view which illustrates a liquid crystal display panel 11 before attachment of a parallax barrier panel 13. FIG. 4 is a plan view which illustrates a liquid crystal display panel 11 to which an adhesive is applied, and the parallax barrier panel 13 to be attached to the liquid crystal display panel 11.

As shown in FIG. 1 and FIG. 2, the liquid crystal display device 1 includes a liquid crystal display panel 11, and a parallax barrier panel 13 as a translucent panel which is attached to the liquid crystal display panel 11 with an adhesive layer 12 interposed between the liquid crystal display panel 11 and the parallax barrier panel 13.

The liquid crystal display device 1 is configured to be a dual view display device for displaying a first image and a second image different from each other and shown in different directions D1 and D2, i.e., left and right directions. That is, the user facing the display screen from the left side of FIG. 1 can see the first image displayed in the direction D1, whereas the user facing the display screen from the right side of FIG. 1 can see the second image displayed in the direction D2.

The liquid crystal display panel 11 includes a display region 15 for displaying an image, and a non-display region 16 which surrounds the display region 15 like a frame. The display region 15 includes a plurality of pixels (not shown) arranged in a matrix. The first image and the second image are alternately displayed at pixels in a row direction (e.g., a horizontal direction of FIG. 1).

The liquid crystal display panel 11 includes a TFT substrate 21 as a first substrate on which a plurality of thin film transistors (hereinafter referred to as TFTs) not shown, etc., are provided, a CF substrate 22 as a second substrate which faces the TFT substrate 21, and a liquid crystal layer 23 provided between the TFT substrate 21 and the CF substrate 22.

The liquid crystal layer 23 is sealed between the TFT substrate 21 and the CF substrate 22 with a frame-like sealing member 24 interposed between the substrates. The sealing member 24 is made, for example, of epoxy resin.

The CF substrate 22 is made, for example, of a transparent substrate, such as a glass substrate having a rectangular shape, and is provided with a color filter (not shown), a common electrode (not shown), etc., on a surface on which the liquid crystal layer 23 is provided. These components, such as the color filter, are covered by an alignment film (not shown).

The TFT substrate 21 is made of a transparent substrate, such as a glass substrate having a rectangular shape larger than the CF substrate 22, and is provided with the TFTs (not shown) mentioned above and a pixel electrode (not shown), etc., on a surface on which the liquid crystal layer 23 is provided. These components, such as the TFTs, are covered by an alignment film (not shown). On the other hand, a polarizing plate (not shown) is attached to a surface of the TFT substrate 21 which is opposite the surface on which the liquid crystal layer 23 is formed.

A plurality of source lines extending in parallel to each other and a plurality of gate lines intersecting the source lines are formed in the display region 15 of the TFT substrate 21. The TFT is located near a position at which the source line and the gate line intersect with each other, and the pixel electrode is connected to each of the TFTs.

The TFT substrate 21 includes a terminal region 18 which does not face the CF substrate 22 and on which a plurality of terminals (not shown) are provided. The terminal region 18 is part of the non-display region 16, and is formed by two adjacent sides of the TFT substrate 21 as shown in FIG. 1.

An integrated circuit (IC) chip 25 as a circuit component, and a flexible printed wiring board (hereinafter referred to as an FPC) 26 as a circuit component are mounted on the terminals in the terminal region 18.

The IC chip 25 is an integrated circuit chip for driving the liquid crystal display panel 11, and a plurality of IC chips 25 are arranged in the terminal region 18 at predetermined intervals. The FPC 26 is for supplying a signal for displaying images and electric power from an external circuit (not shown) to the liquid crystal display panel 11. The FPC 26 is located such that, for example, one end is along one side of the TFT substrate

Although not shown, the IC chips 25 and the FPC 26 are mounted on the terminals via an anisotropic conductive film (ACF) formed by dispersing conductive particles in an insulating adhesive.

As shown in FIG. 1 and FIG. 2, the parallax barrier panel 13 has a rectangular plate-like shape, and is attached to a surface of the CF substrate 22 which is opposite the surface facing the TFT substrate 21, with the adhesive layer 12 interposed between the CF substrate 22 and the parallax barrier panel 13. The adhesive layer 12 is made of a resin material, such as ultraviolet curing resin. The parallax barrier panel 13 covers the entire display region 15.

The parallax barrier panel 13 includes a transparent substrate, such as a glass substrate. A parallax barrier (not shown) having slits for separating display light such that the first image is viewable from the direction D1 and the second image is viewable from the direction D2, is provided on a surface of the glass substrate facing the liquid crystal display panel 11. On the other hand, a polarizing plate (not shown) is attached to a surface of the parallax barrier panel 13 which is opposite the surface facing the liquid crystal display panel 11.

The pattern shape of the parallax barrier is not specifically limited to slits, but may be zigzag pattern or delta pattern.

As shown in FIG. 1 and FIG. 2, at least part of the FPC 26 and the IC chips 25 is covered by the adhesive layer 12 extending from between the CF substrate 22 and the parallax barrier panel 13. In particular, each IC chip 25 is entirely covered by the adhesive layer 12. On the other hand, the FPC 26 is covered by the adhesive layer 12 at the portion where the FPC 26 and the terminal in the terminal region 18 are connected together.

Accordingly, the liquid crystal display device 1 is configured to show the first image and the second image by controlling the state of alignment of liquid crystal molecules by applying a voltage to the liquid crystal layer 23 in each of the pixels according to a signal input to the liquid crystal display panel 11 via the FPC 26 and the IC chips 25, and allow the first image and the second image to be separately displayed in the left and right directions D1, D2 using the parallax barrier panel 13.

Fabrication Method

A method for fabricating the liquid crystal display device 1 will be described below.

The liquid crystal display device 1 is fabricated by attaching a parallax barrier panel 13 to a liquid crystal display panel 11 with an adhesive layer 12 interposed therebetween.

Specifically, a TFT substrate 21 and a CF substrate 22 are formed in the first step. These substrates 21, 22 are attached to each other with a sealing member 24 interposed therebetween, and a liquid crystal layer 23 is sealed between the substrates 21, 22 by the sealing member 24. Here, the substrates 21, 22 are attached to each other so that the substrates 21, 22 are aligned such that a terminal region 18 of the TFT substrate 21 does not overlap with the CF substrate 22 and is exposed. A terminal region is formed in the area of the TFT substrate 21 where the TFT substrate 21 does not face the CF substrate 22. The liquid crystal display panel 11 is fabricated in this manner.

After that, in the third step, an IC chip 25 and an FPC 26 are press fitted to terminals in the terminal region 18 of the TFT substrate 21 via an ACF.

On the other hand, a parallax barrier with slits is provided to a surface of a glass substrate, thereby separately forming a parallax barrier panel 13. The material for the parallax barrier is not specifically limited. The parallax barrier may be formed, for example, of a photosensitive resin in which a black pigment is dispersed, or may be formed by patterning a metal thin film by photolithography, etc.

In the second step, as shown in FIG. 4, an ultraviolet curing resin as the adhesive layer 12 is applied to a surface of the CF substrate 22 of the liquid crystal display panel 11 to which surface the parallax barrier panel 13 is to be attached, by spin coating or slit coating, for example. After that, the parallax barrier panel 13 is attached to the CF substrate 22 to which the adhesive layer 12 is applied. To properly display the first image and the second image separately in the left and right directions D1, D2 of the liquid crystal display device 1, it is preferable, for example, to make an alignment mark on each of the liquid crystal display panel 11 and the parallax barrier panel 13, and bring the parallax barrier panel 13 into correct alignment using the alignment marks.

Next, the parallax barrier panel 13 is pushed toward the liquid crystal display panel 11. As shown in FIG. 1 and FIG. 2, part of the adhesive layer 12 is squeezed out from between the liquid crystal display panel 11 and the parallax barrier panel 13 to the terminal region 18. As a result, the entire IC chip 25 and a portion of the FPC 26 mounted to the terminal region 18 are covered by the adhesive layer 12.

After that, the adhesive layer 12 is subjected to UV irradiation, thereby curing the adhesive layer 12 to make the parallax barrier panel 13 to totally adhere to the liquid crystal display panel 11. The liquid crystal display device 1 in FIG. 1 is fabricated in this manner.

### Advantages of First Embodiment

According to the first embodiment, at least part of the IC chip 25 and the FPC 26 mounted on the terminals in the terminal region 18 is covered by the adhesive layer 12 extending from between the CF substrate 22 and the parallax barrier panel 13. Thus, unlike the conventional cases, the adhesive layer 12 does not need to be removed from the terminals region 18 and cleaned. This eliminates the need to perform a step of cleaning the adhesive layer 12. Accordingly, the number of steps necessary for fabricating the liquid crystal display device 1 can be reduced. Further, since the adhesive layer 12 is not removed from the terminal region 18, it is possible to prevent separation of the terminal associated with the removal step. As a result, it is possible to reduce the time necessary for the fabrication, and significantly increase the yield.

Moreover, the portion where the IC chip 25 and the FPC 26 are mounted can be protected by the adhesive layer 12 which is for attaching the parallax barrier panel 13 to the liquid crystal display panel 11. Thus, the IC chip 25 and the FPC 26 are more firmly mounted on the terminals of the terminal region 18 without an increase in the number of steps.

Further, the entire IC chip 25 is covered by the adhesive layer 12. Thus, the IC chip 25 can be more firmly mounted on the terminals, and the IC chip 25 can be advantageously protected from the external environment.

Further, the portion where the FPC 26 is mounted is covered by the adhesive layer 12. Thus, the FPC 26 can be more firmly mounted on the terminals, and the state of mounting can be advantageously maintained even when a tensile stress is applied to the FPC 26 from the outside.

Accordingly, it is possible to provide a dual view display device of which the number of fabrication steps can be reduced and the yield can be increased, by attaching the parallax barrier panel 13 to the CF substrate 22 via the adhesive layer 12.

### Second Embodiment of Invention

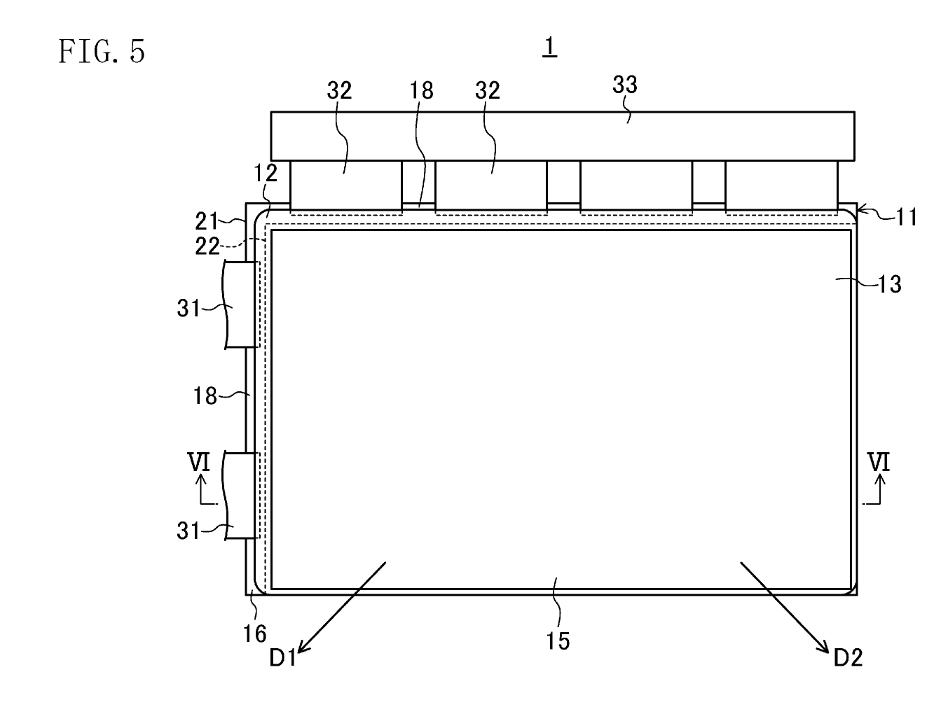

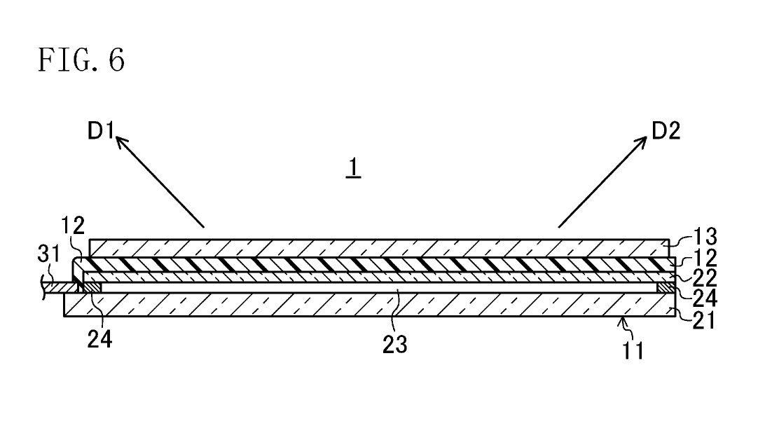

FIG. 5 and FIG. 6 show the second embodiment of the present invention.

FIG. 5 is a plan view which illustrates an external view of a main part of a liquid crystal display device 1 according to the present second embodiment. FIG. 6 is a cross section taken along the line VI-VI of FIG. 5. In each of the following embodiments, same reference numerals have been used to designate the same elements as the elements shown in FIG. 1 to FIG. 4, and explanation thereof is omitted.

The first embodiment and the second embodiment are different from each other in that the circuit components are the IC chip 25 and the FPC 26 in the first embodiment, whereas the circuit components are drivers TCP 31, 32 in the present second embodiment.

Specifically, according to the present embodiment, a plurality of drivers TCP 31 as gate drivers are mounted on a terminal region 18 along one of two adjacent sides of a TFT substrate 21, whereas a plurality of drivers TCP 32 as source drivers are mounted on the terminal region 18 along the other side of the two adjacent sides of the TFT substrate 21.

The ends of the plurality of drivers TCP 32 opposite to the ends mounted on the terminal region 18 are connected to a single wiring board 33. Thus, it is possible to transmit signals among the drivers TCP 32.

The portion where the drivers TCP 31, 32 are mounted is covered by the adhesive layer 12 squeezed out from between the parallax barrier panel 13 and the CF substrate 22 as in the first embodiment.

### Advantages of Second Embodiment

In the second embodiment, portions of the drivers TCP 31, 32 as circuit components which portions are mounted on the terminal region 18 is covered by the adhesive layer 12. This eliminates the need to perform a step of cleaning the adhesive layer 12. Accordingly, the number of steps necessary for fabricating the liquid crystal display device 1 can be reduced in the second embodiment, as well. Further, since the adhesive layer 12 is not removed from the terminal region 18, it is possible to prevent separation of the terminals associated with the removal step. As a result, it is possible to reduce the time necessary for the fabrication, and significantly increase the yield.

Moreover, the portions where the drivers TCP 31, 32 are provided can be protected by the adhesive layer 12 which is for attaching the parallax barrier panel 13 to the liquid crystal display panel 11. Thus, the drivers TCP 31, 32 are more firmly mounted on the terminals of the terminal region 18 without increasing the number of fabrication steps.

### Third Embodiment of Invention

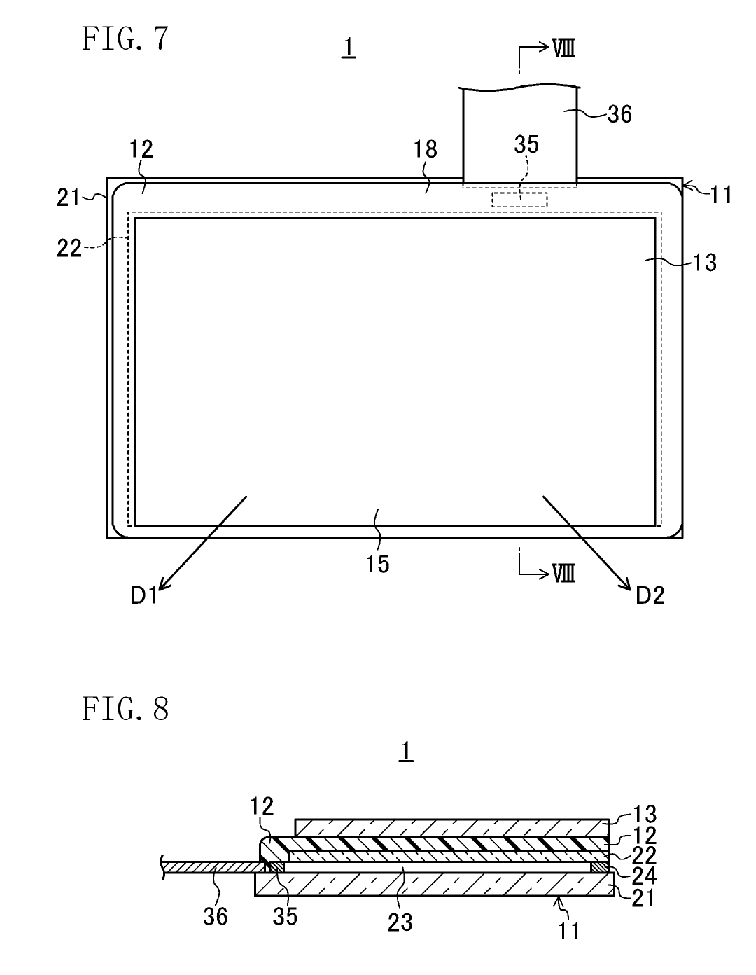

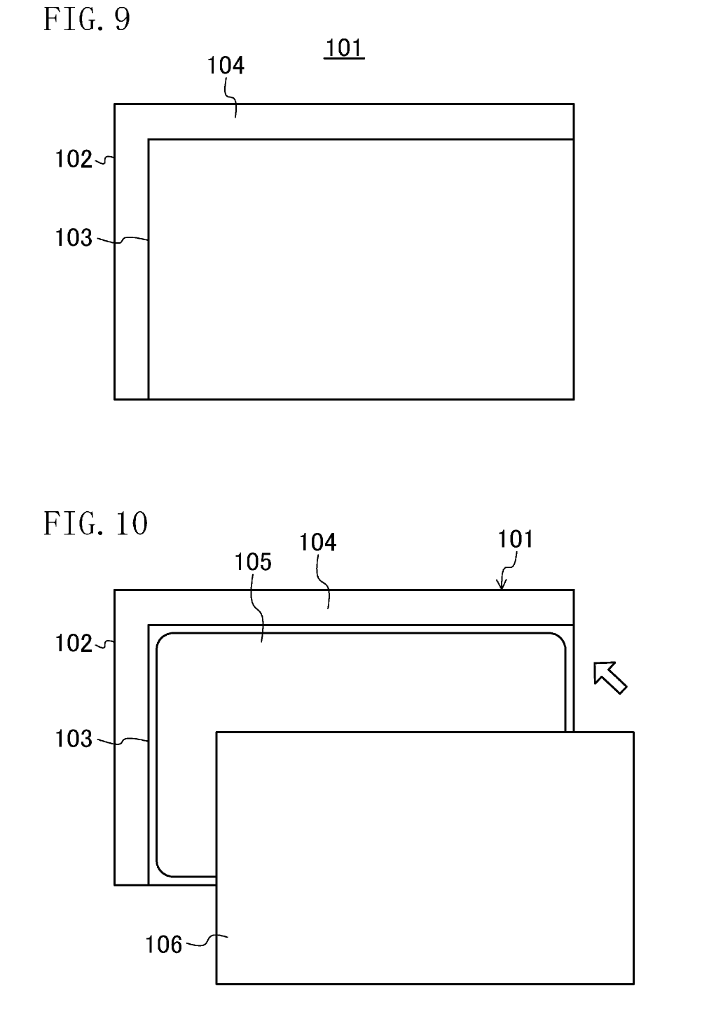

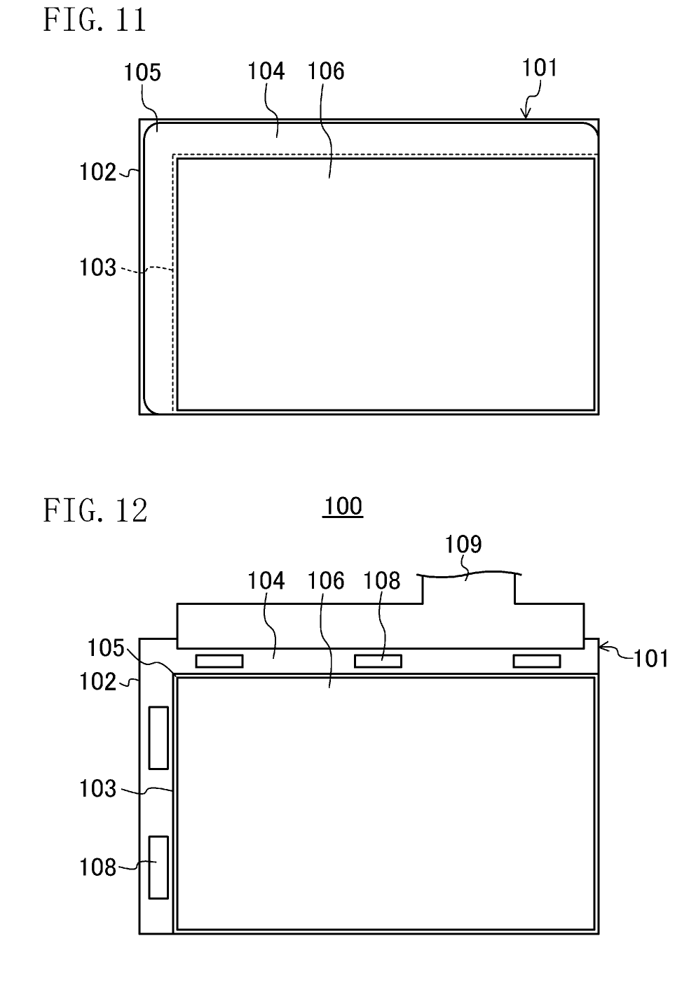

FIG. 7 and FIG. 8 show the third embodiment of the present invention.

FIG. 7 is a plan view which illustrates an external view of a main part of a liquid crystal display device 1 according to the present third embodiment. FIG. 8 is a cross section taken along the line VIII-V111 of FIG. 7.

The first embodiment and the present third embodiment are different from each other in that the circuit components are the IC chip 25 and FPC 26 in the first embodiment, whereas the circuit components are one chip driver 35 and an FPC 36 in the third embodiment. The one chip driver 35 is comprised of a plurality of control circuits, such as a source driver and a gate driver, configured as one chip.

According to the present embodiment, one end of the FPC 36 is mounted on a terminal region 18 along one side of a TFT substrate 21, and the one chip driver 35 is located between the portion where the FPC 36 is mounted and a display region 15.

The one chip driver 35 is entirely covered by the adhesive layer 12. The portion of the FPC 36 which is mounted on the terminal region 18 is covered by the adhesive layer 12 squeezed out from between the parallax barrier panel 13 and the CF substrate 22.

### Advantages of Third Embodiment

In the third embodiment, the entire one chip driver 35 as a circuit component, and part of the FPC 36 as a circuit component which part is mounted on the terminal region 18 are covered by the adhesive layer 12. This eliminates the need to perform a step of cleaning the adhesive layer 12. Accordingly, the number of steps necessary for fabricating the liquid crystal display device 1 can be reduced in the third embodiment, as well. Further, since the adhesive layer 12 is not removed from the terminal region 18 as in the first embodiment, it is possible to prevent separation of the terminals associated with the removal step. As a result, it is possible to reduce the time necessary for the fabrication, and significantly increase the yield.

Moreover, the portions where the one chip driver 35 and the FPC 36 are mounted can be protected by the adhesive layer 12 which is for attaching the parallax barrier panel 13 to the liquid crystal display panel 11. Thus, the one chip driver 35 and the FPC 36 are more firmly mounted on the terminals of the terminal region 18 without increasing the number of fabrication steps.

### Other Embodiments

In the first to third embodiments, a liquid crystal display device 1 is described as an example of a dual view display device. However, the present invention is not limited to the liquid crystal display device, and may also be applied to a structure in which the parallax barrier panel 13 is replaced by another translucent panel, such as a touch panel, to be attached to the display panel.

Further, the display panel according to the present invention is not limited to the liquid crystal display panel, and may be other display panels, such as an organic EL display panel and plasma display panel.

### INDUSTRIAL APPLICABILITY

As described above, the present invention is useful as a display device, such as a liquid crystal display device, etc., and a method for fabricating the display device.

### DESCRIPTION OF REFERENCE CHARACTERS

1 liquid crystal display device
11 liquid crystal display panel
12 adhesive layer
13 parallax barrier panel (translucent panel)
18 terminal region
21 TFT substrate (first substrate)
22 CF substrate (second substrate)
25 IC. chip (circuit component)
26 FPC (circuit component)
31, 32 driver TCP (circuit component)
35 1 chip driver (circuit component)
36 FPC (circuit component)

1. A display device comprising:
a display panel including a first substrate and a second substrate facing the first substrate, and
a translucent panel attached, via an adhesive layer, to a surface of the second substrate opposite a surface facing the first substrate, wherein
the first substrate includes a terminal region which does not face the second substrate and in which a plurality of terminals are provided,
a circuit component is mounted on the terminals in the terminal region, and
at least part of the circuit component is covered by the adhesive layer extending from between the second substrate and the translucent panel to the terminal region.

2. The display device of claim 1, wherein
the circuit component is an IC chip, and
the entire IC chip is covered by the adhesive layer.

3. The display device of claim 1, wherein
the circuit component is a flexible printed circuit board, and
a connecting portion at which the flexible printed circuit board and the terminals of the terminal region are connected is covered by the adhesive layer.

4. The display device of claim 1, wherein
the translucent panel is a parallax barrier panel.

5. The display device of claim 1, wherein
the display panel is a liquid crystal display panel.

6. A method for fabricating a display panel, comprising:
a first step in which a first substrate and a second substrate are attached to each other to form a display panel, and
a second step in which a translucent panel is attached, via an adhesive layer, to a surface of the second substrate of the display panel opposite a surface facing the first substrate, wherein
the first step includes forming a terminal region in which a plurality of terminals are provided, in a region of the first substrate which does not face the second substrate,
the method includes a third step between the first step and the second step, in which a circuit component is mounted on the terminal region in the first substrate of the display panel, and
the second step includes squeezing part of the adhesive layer out from between the display panel and the translucent panel to the terminal region, thereby covering at least part of the circuit component mounted on the terminal region by the adhesive layer.

7. The method for fabricating the display device of claim 6, wherein
the circuit component is an IC chip, and
the entire IC chip is covered by the adhesive layer.

8. The method for fabricating the display device of claim 6, wherein
the circuit component is a flexible printed circuit board, and
a connecting portion at which the flexible printed circuit board and the terminals in the terminal region are connected is covered by the adhesive layer.

9. The method for fabricating the display device of claim 6, wherein
the translucent panel is a parallax barrier panel.

10. The method for fabricating the display device of claim 6, wherein
the display panel is a liquid crystal display panel.
